(19) United States
(12) Patent Application Publication
(10) Pub. No.: US 2014/0334512 A1
(43) Pub. Date: Nov. 13, 2014

(54) DISTRIBUTED FEEDBACK LASER DIODE AND MANUFACTURING METHOD THEREOF

(71) Applicant: Electronics and Telecommunications Research Institute, Daejeon (KR)

(72) Inventors: Oh Kee KWON, Daejeon (KR); Young-Tak HAN, Daejeon (KR); Chul-Wook LEE, Daejeon (KR); Young Ahn LEEM, Daejeon (KR)

(73) Assignee: Electronics and Telecommunications Research Institute, Daejeon (KR)

(21) Appl. No.: 14/197,910

(22) Filed: Mar. 5, 2014

(30) Foreign Application Priority Data
May 10, 2013 (KR) 10-2013-0053160

(51) Int. Cl. H01S 5/12; H01S 5/32

(52) U.S. Cl. CPC H01S 5/12; H01S 5/3216
USPC 372/45.012; 438/31; 372/45.01

(57) ABSTRACT

Provided is a distributed feedback-laser diode (DFB-LD) and manufacturing method thereof. The DFB-LD includes a substrate; a lower clad layer having a grating on the substrate; an active waveguide extended in a first direction on the lower clad layer; an upper clad layer on the active waveguide; a signal pad on the upper clad layer; and at least one ground pad spaced apart from the active waveguide, the upper clad layer, and the signal pad in a second direction crossing the first direction, the at least one ground pad being coupled to the lower clad layer.

### CROSS-REFERENCE TO RELATED APPLICATIONS

This U.S. non-provisional patent application claims priority under 35 U.S.C. §119 of Korean Patent Application No. 10-2013-0053160, filed on May 10, 2013, the entire contents of which are hereby incorporated by reference.

### BACKGROUND OF THE INVENTION

The present invention disclosed herein relates to an optical device and a manufacturing method thereof, and more particularly, to a single mode distributed feedback-laser diode and a manufacturing method thereof.

A high speed modulated laser includes a distributed feedback-laser diode (DFB-LD). The DFB-LD has bee applied to various types of optical communication systems because it has excellent lasing characteristics and modulation characteristics. The modulation characteristics of elements are mainly affected by the resonant characteristics and parasitic effect of laser diodes, and single mode characteristics have a close relation to the structure variables of elements including the coupling coefficients of grating.

The DFB-LD has a structure in which a grating layer is axially formed over or under an active layer. A refractive index or loss is regularly repeated on the grating layer. Laser light may be lased at a wavelength that satisfies the refractive index change structure of the grating layer, namely, Bragg condition by an index-coupled grating. A ridge waveguide is disposed over the active layer. Laser light may be delivered along the ridge waveguide. A metal pad for a signal line may be disposed over the ridge waveguide. In the case of a general DFB-LD, a metal pad (ground pad) for ground connection is disposed under a substrate. In this case, the modulation characteristics of laser light needs to be measured by external modulated electrical signals. The external modulated electrical signals may are delivered through a high frequency probe of which the form may include ground-signal-ground GSG, ground-signal GS, and ground-signal(−)-signal(+)-ground GSSG. Since a typical DFB-LD has no ground pad exposed on a waveguide, it has a drawback in that it is difficult to measure a laser diode directly by using the high frequency probe.

Thus, a separate mount that may be in contact with the high frequency probe is needed to measure the modulation characteristics of a laser diode, and signal lined disposed on the mount needs to be wire bonded to the laser diode. When measuring modulation characteristics on the above-described structure, it is difficult to evaluate the characteristics of elements themselves because there are effects provided by the mount and wire bonding in addition to the characteristics of the laser diode.

### SUMMARY OF THE INVENTION

The present invention provides a distributed feedback laser diode and a manufacturing method thereof that may easily measure modulation characteristics by using a high frequency probe.

Embodiments of the inventive concept provide distributed feedback-laser diodes (DFB-LD) include a substrate; a lower clad layer having a grating on the substrate; an active waveguide extended in a first direction on the lower clad layer; an upper clad layer on the active waveguide; a signal pad on the upper clad layer; and at least one ground pad spaced apart from the active waveguide, the upper clad layer, and the signal pad in a second direction crossing the first direction, the at least one ground pad being coupled to the lower clad layer.

In some embodiments, the upper clad layer may include a first upper clad layer covering an entire surface of the active waveguide; and a second upper clad layer forming a ridge waveguide of the first upper clad layer.

In other embodiments, the second upper clad layer may have a reverse mesa structure of an inverted triangle in the second direction.

In still other embodiments, the upper clad layer may further include an etch stop layer between the first upper clad layer and the second upper clad layer.

In even other embodiments, the etch stop layer may define a depth or thickness of the reverse mesa structure.

In yet other embodiments, the distributed feedback-laser diode may further include a passivation layer covering the lower clad layer and the first upper clad layer; and a first contact plug passing through the passivation layer, the first contact plug disposed between the ground pad and the lower clad layer.

In further embodiments, the passivation layer may include a first passivation layer disposed on the lower clad layer and the upper clad layer and on sidewalls of the lower clad layer and the upper clad layer; and a second passivation layer covering the first passivation layer, the second passivation layer being formed in the same height as the upper clad layer.

In still further embodiments, the distributed feedback-laser diode may further include an omic contact layer and a second contact plug between the second upper clad layer and the signal pad.

In even further embodiments, the ground pad and the signal pad may be arranged in a ground-signal-ground GSG structure in the second direction.

In yet further embodiments, the active waveguide may have a multiple quantum well structure.

In other embodiments of the inventive concept, methods of manufacturing a distributed feedback-laser diode include forming a lower clad layer on a substrate; forming an active waveguide and an upper clad layer in a first direction on the lower clad layer; forming a protective layer disposed on the upper clad layer and the lower clad layer and, the passivation layer having contact holes through which portions of the upper clad layer and the lower clad layer are exposed; and forming a signal pad and a ground pad electrically coupled to the upper clad layer and the lower clad layer respectively through the contact holes.

In some embodiments, the forming of the active waveguide and the upper clad layer may include forming the active waveguide on the lower clad layer; forming a first upper clad layer on the active waveguide; forming an etch stop layer on the first upper clad layer; forming a second upper clad layer on the etch stop layer; forming an omic contact layer on the second upper clad layer; and etching the omic contact layer, the second upper clad layer, and the etch stop layer to have a reverse mesa structure of an inverted triangle.

In other embodiments, the etching of the omic contact layer, the second upper clad layer, and the etch stop layer may be performed by using wet solution including hydrogen bromide or hydrogen chloride.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concept and, together with the description, serve to explain principles of the present invention. In the drawings:

FIG. 1 is a schematic perspective view of a distributed feedback-laser diode (DBF-LD) according to a first embodiment of the inventive concept;

FIG. 2 is a sectional view of FIG. 1;

FIG. 3 is plane views of FIG. 1 and a high frequency probe module;

FIGS. 4 and 5 are plane views of other examples of a signal pad, a ground pad, and a high frequency probe module;

FIGS. 6 to 14 are sectional views of a method of manufacturing the DBF-LD according to the first embodiment of the inventive concept based on FIG. 2; and

FIG. 15 shows a DBF-LD according to a second embodiment of the inventive concept.

### DETAILED DESCRIPTION OF PREFERRED EMBODIMENTS

Exemplary embodiments will be described below with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to an ordinary person skill in the art. Further, the present invention is only defined by scopes of claims. Like reference numerals refer to like elements throughout.

In the following description, the technical terms are used only for explaining specific embodiments while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto. It will be understood that when an element such as a layer, film, region, or substrate is referred to as being “on” another element, it can be directly on the other element or intervening elements may also be present.

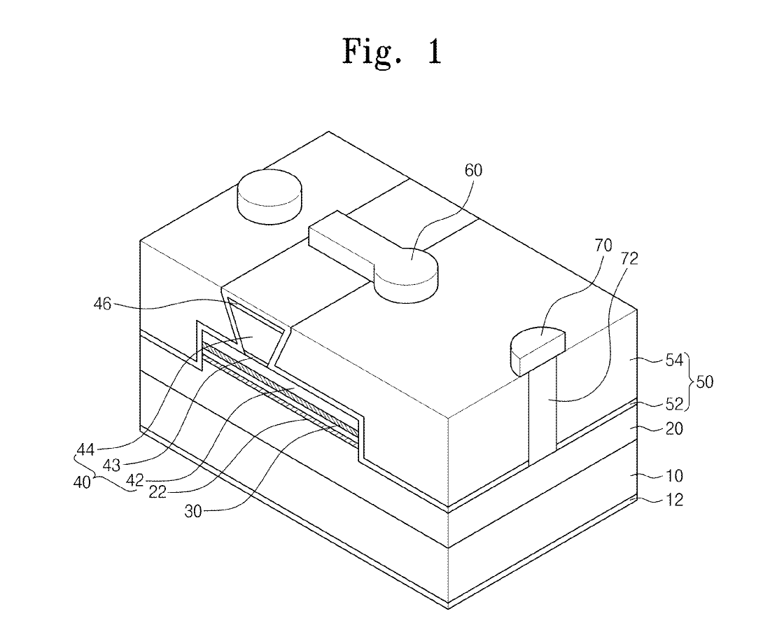

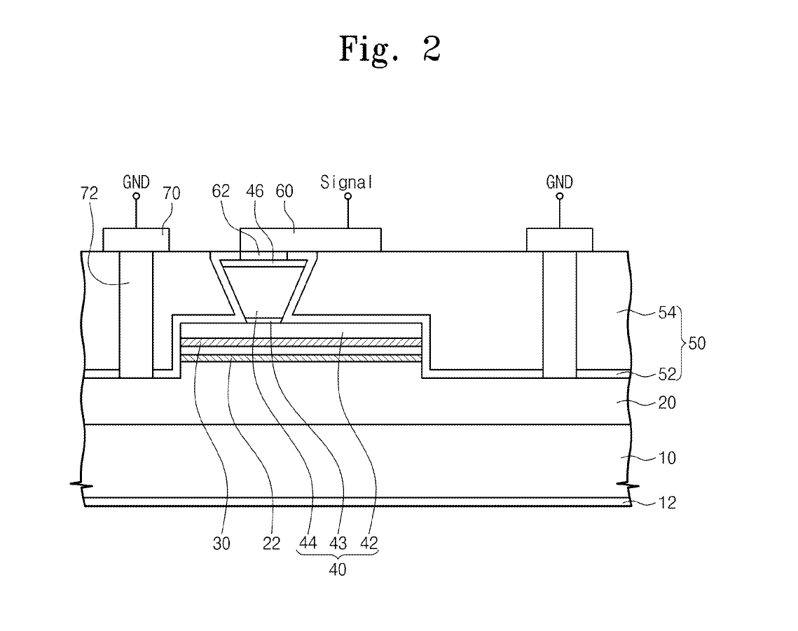

FIG. 1 is a schematic perspective view of a distributed feedback-laser diode (DBF-LD) according to a first embodiment of the inventive concept, and FIG. 2 is a sectional view of FIG. 1.

Referring to FIGS. 1 and 2, the DBF-LD according to a first embodiment of the inventive concept includes a substrate 10, a lower clad layer 20, an active waveguide 30, an upper clad layer 40, a passivation layer 50, a signal pad 60, and a ground pad 70.

The substrate 10 may include silicon doped with N-type impurities, gallium nitride GaN, or gallium arsenide GaAs. A ground plate 12 is coupled to the bottom of the substrate 10.

The lower clad layer 20 is disposed on the substrate 10. The lower clad layer 20 may include N-type InP, AlGaAs, and InGaP. A grating 22 may be disposed on the lower clad layer 20. The active wavelength 30 is extended on the lower clad layer 20 in a first direction. The active waveguide may include a multiple quantum well structure of InGaAsP, InGaAlAs, AlGaAs, GaAs, and InGaAs. If a voltage is applied to the active waveguide 30, laser light having a wavelength corresponding to the interval of gratins 22 is lased. The present invention is not limited thereto. The active waveguide 30 may generate a signal voltage according to the potential between the lower clad layer 20 and the upper clad layer 40.

The upper clad layer 40 is disposed on the active waveguide 30. The upper clad layer 40 may be a ridge waveguide that is formed along the active waveguide 30. The upper clad layer 40 may include P-type InP, AlGaAs, and InGaP. The upper clad layer 40 may include a first upper clad layer 42, an etch stop layer 43, and a second upper clad layer 44. The first upper clad layer 42 covers the entire surface of the active waveguide 30. The etch stop layer 43 is disposed between the first upper clad layer 42 and the second upper clad layer 44. The etch stop layer 43 and the second upper clad layer 44 may have a section having a reverse mesa structure of an inverted triangle. The above-described product is exemplarily provided only for understanding the technical spirit of the present invention. As such, the technical spirit of the present invention is not limited to the above-described product. That is, the etch stop layer 43 may be formed to have the same area as the first upper clad layer 42. The present invention is not limited thereto, but an omic contact layer 43 is disposed on the upper clad layer 40.

The passivation layer 50 covers the lower clad layer 20, the upper clad layer 40, and the omic contact layer 46. The passivation layer 50 is formed as a silicon oxide film or a silicon nitride film that is a dielectric. The passivation layer 50 includes a first passivation layer 52 and a second passivation layer 54. The first passivation layer 52 is disposed on the lower clad layer 20, the active waveguide 30, the upper clad layer 40, and the omic contact layer 46 and on sidewalls thereof. The second passivation layer 54 is disposed on the first passivation layer 52. The second passivation layer 54 may have the same height as the second upper clad layer 44 or the omic contact layer 46.

The signal pad 60 is disposed on the omic contact layer 46 and the second passivation layer 54. The omic contact layer 46 is coupled to the signal pad 60 by a first contact plug 62.

The ground pad 70 is electrically connected to the lower clad layer 20 by a second contact plug 72. The second contact plug 72 passes through the passivation layer 50. The signal pad 60 and the ground pad 70 are disposed in the same height on the passivation layer 50.

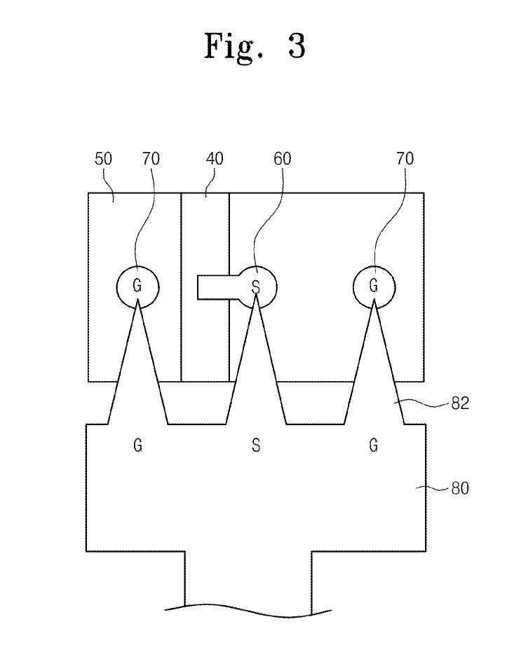

FIG. 3 is plane views of FIG. 1 and a high frequency probe module 80. The signal pad 60 and the ground pad 70 are arranged in a GSG structure. The high frequency probe module 80 may be connected to the signal pad 60 and the ground pad 70. The high frequency probe module 80 may directly detect modulation characteristics during the operation of a laser diode. The high frequency probe module 80 may have a plug 84 and a plurality of probes 82 that is fixed to the plug 84. The probes 82 may have the same length. The probes 82 may be connected simultaneously to the signal pad 60 and the ground pad 70.

Thus, the DBF-LD according to an embodiment of the inventive concept may easily perform external direct modulation characteristic measurement during the operation.

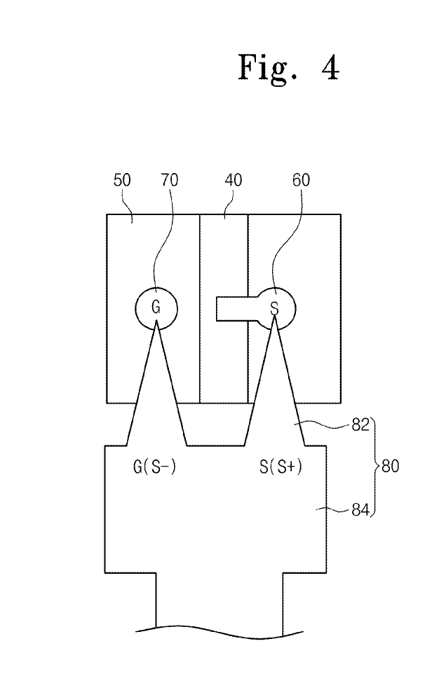

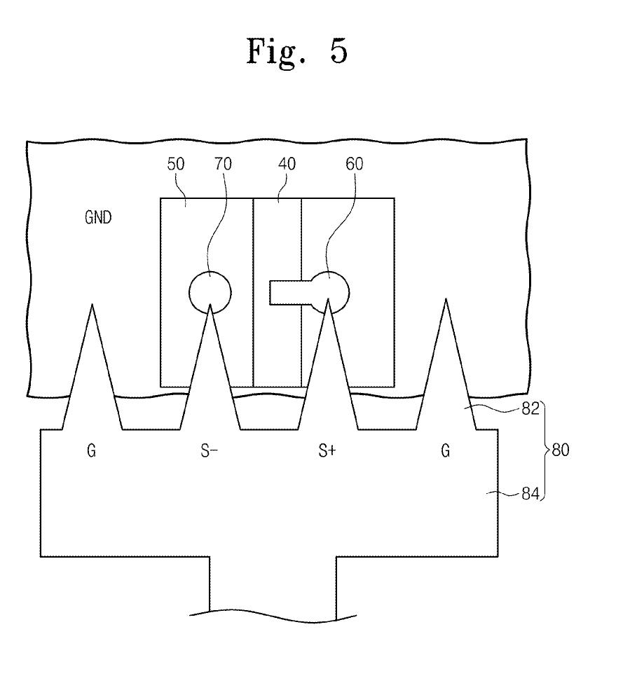

FIGS. 4 and 5 show other examples of the signal pad 60, the ground pad 70, and the high frequency probe module 80. The signal pad 60 and the ground pad 70 are arranged in a GS or GSSG structure.

A method of manufacturing such a DFB-LD according to the first embodiment of the inventive concept is as follows.

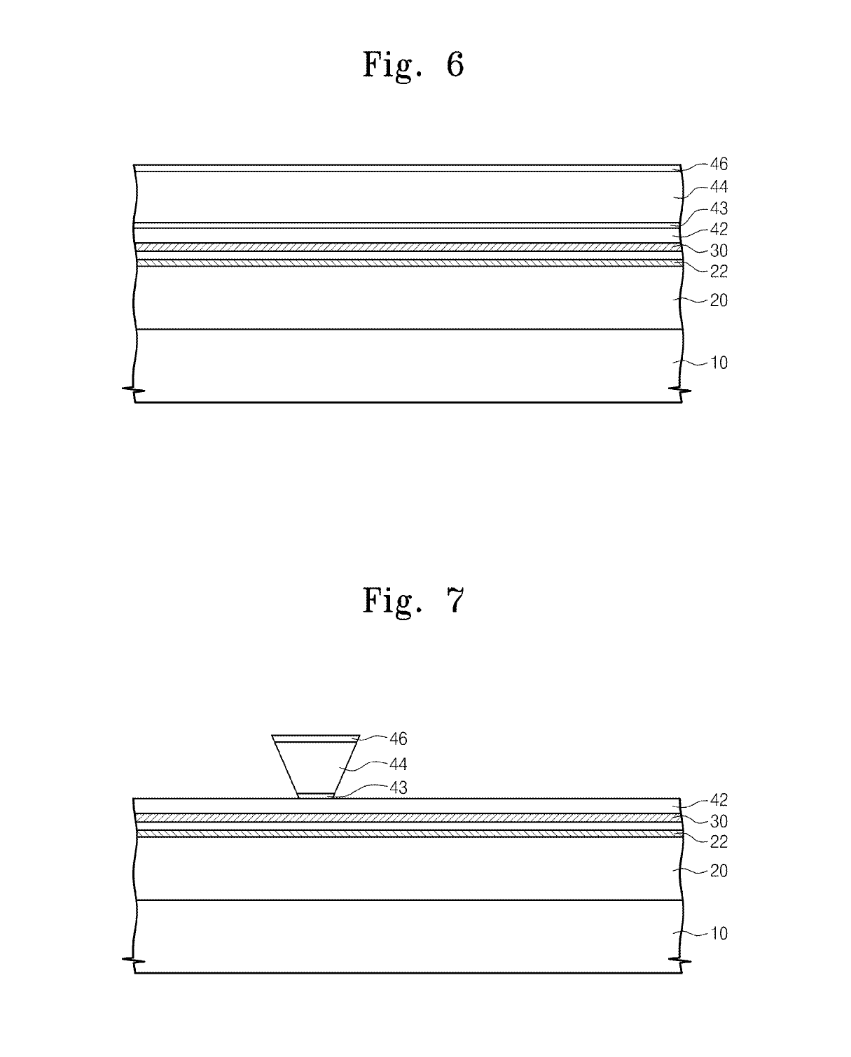

FIGS. 6 to 14 are sectional views of a method of manufacturing the DBF-LD according to the first embodiment of the inventive concept based on FIG. 2.

Referring to FIG. 6, the lower clad layer 20, the active waveguide 30, the first upper waveguide layer 42, the etch stop layer 43, the second upper waveguide layer 44, and the omic contact layer 46 are formed on the substrate 10. The lower clad layer 20 may include a III-V group semiconductor layer that is formed by using a chemical vapor deposition process. The III-V group semiconductor layer includes N-type InP, AlGaAs, and InGaP. The lower clad layer 20 may have the grating 22. The active waveguide 30, the first upper clad layer 42, the etch stop layer 43, and the second upper clad layer 44 may include a III-V group semiconductor layer that is formed on the entire surface of the lower clad layer 20 by using a chemical vapor deposition process. The III-V group semiconductor layer includes P-type InP, AlGaAs, and InGaP. The omic contact layer 46 may include metal such as gold or chrome.

Referring to FIG. 7, the omic contact layer 46, the second upper clad layer 44, and the etch stop layer 43 are etched to be patterned as a reverse mesa structure having a section of an inverted triangle. The reverse mesa structure may be formed by performing a photolithography or etching process on the omic contact layer 46, the second upper clad layer 44, and the etch stop layer 43. The etching process may be performed by using etchant including hydrogen bromide (HBr) or hydrogen chloride (HCl). The etch stop layer 43 may define the depth or thickness of the reverse mesa structure in the etching process.

Referring to FIG. 8, the first upper clad layer 42, the active waveguide 30, and the lower clad layer 20 are etched. Here, the lower clad layer 20 may be etched to under the grating 22. The first upper clad layer 42, the active waveguide 30, and the lower clad layer 20 are extended in a first direction.

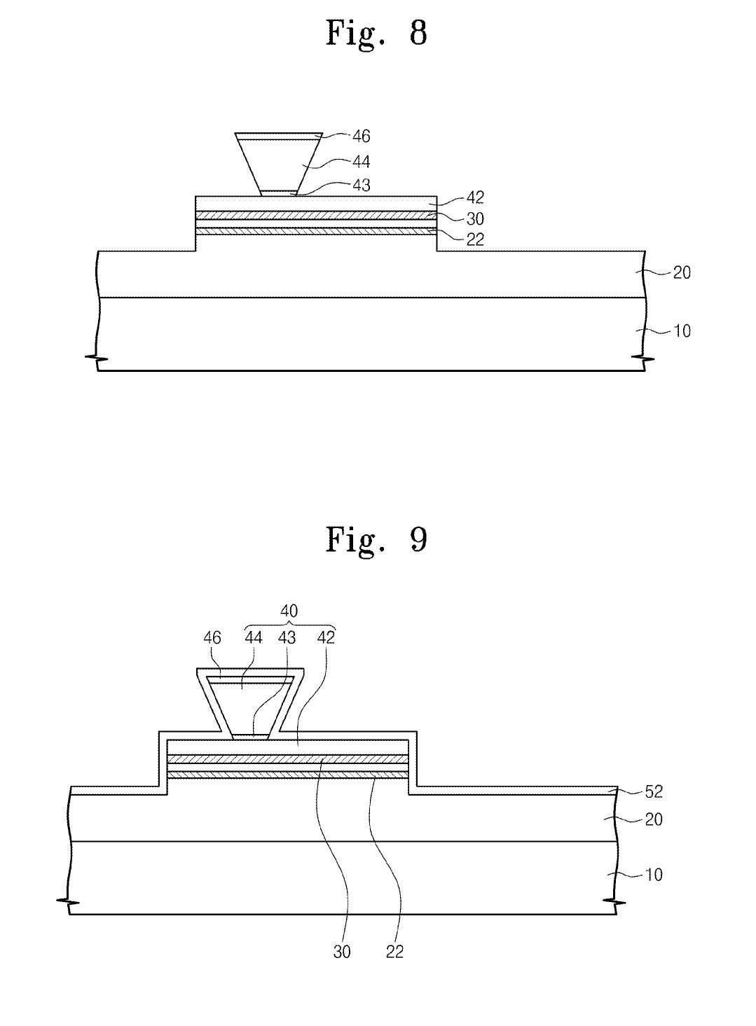

Referring to FIG. 9, the passivation layer 50 is formed on the lower clad layer 20, the upper clad layer 40, and the omic contact layer 46. The first passivation layer 52 may include a silicon oxide film or a silicon nitride film that is formed by using a chemical vapor deposition process. The first passivation layer 52 is formed on the lower clad layer 20 and the upper clad layer 40 and on sidewalls thereof.

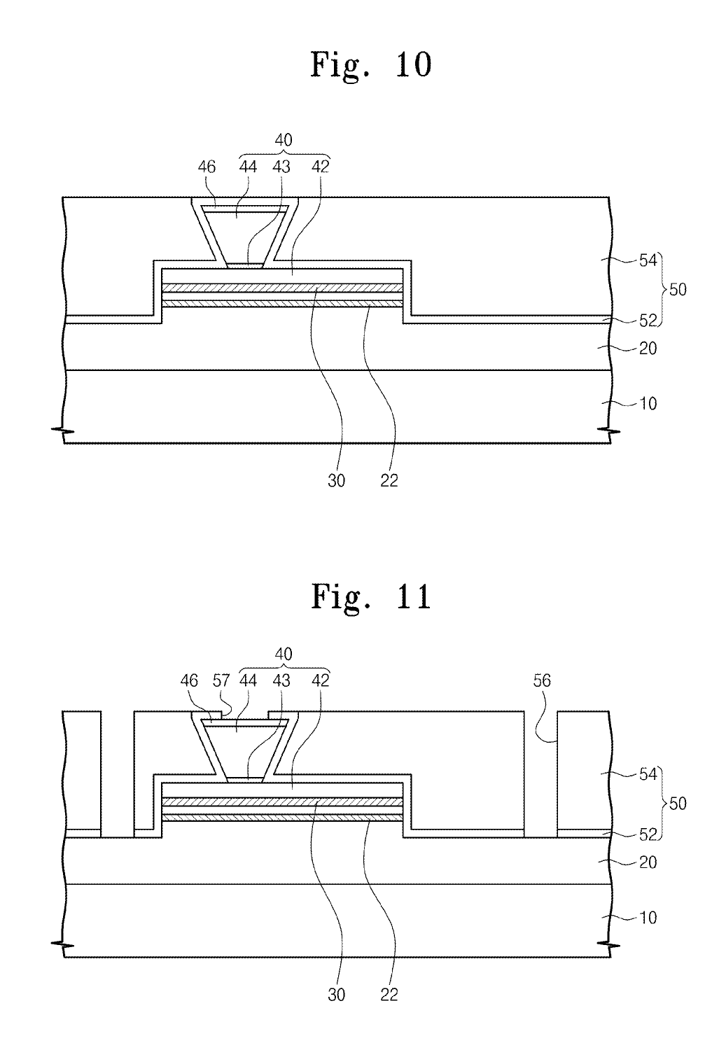

Referring to FIG. 10, the second passivation layer 54 is formed on the first passivation layer 52. The second passivation layer 54 may include a polymer based organic compound or a dielectric that is a silicon oxide film or a silicon nitride film. The second passivation layer 54 may be formed to be even with the substrate 10.

Referring to FIG. 11, a first contact hole and second contact holes 56 are formed by removing the passivation layer 50 from the lower clad layer 20 and the omic contact layer 46. The second passivation layer 54 of the passivation layer 50 may be removed by using photolithography and etching processes.

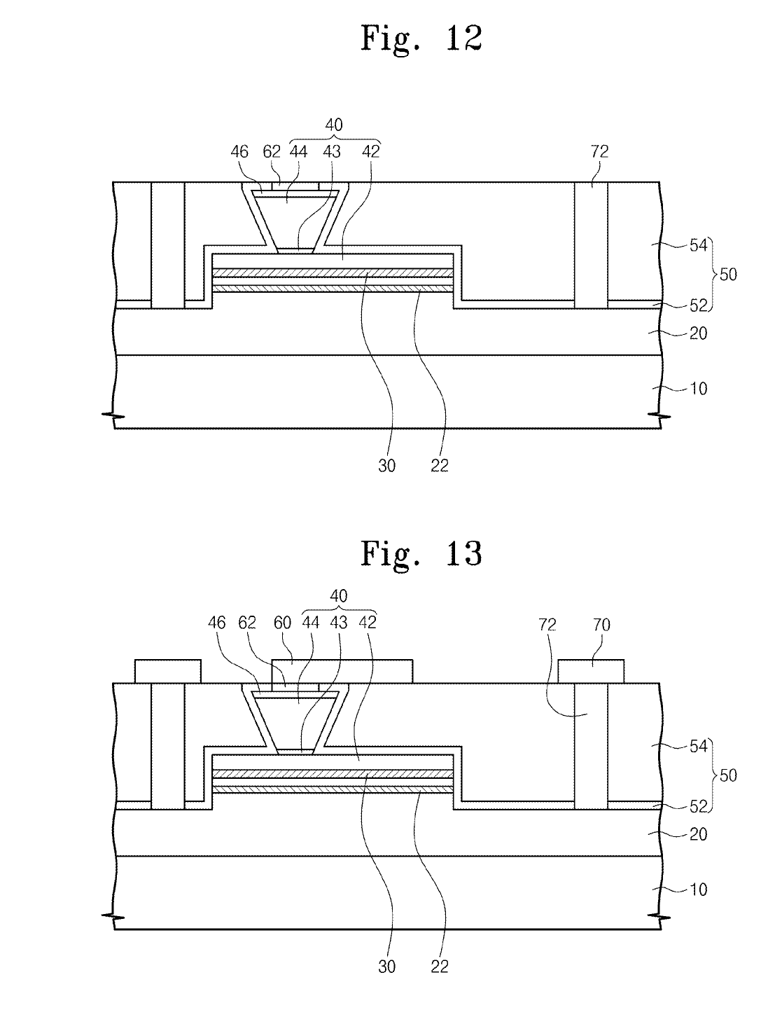

Referring to FIG. 12, the first contact plug 62 and the second contact plugs 72 are respectively formed in the first contact hole 56 and the second contact holes 57. The first and second contact plugs 62 and 72 may be formed by performing a deposition process and a chemical mechanical processing (CMP) process on a metal layer.

Referring to FIG. 13, the ground pads 70 and the signal pad 60 are formed on the first contact plug 62 and the second contact plugs 72. The ground pads 70 and the signal pad 60 are formed by performing deposition, photolithography, and etching processes on the metal layer.

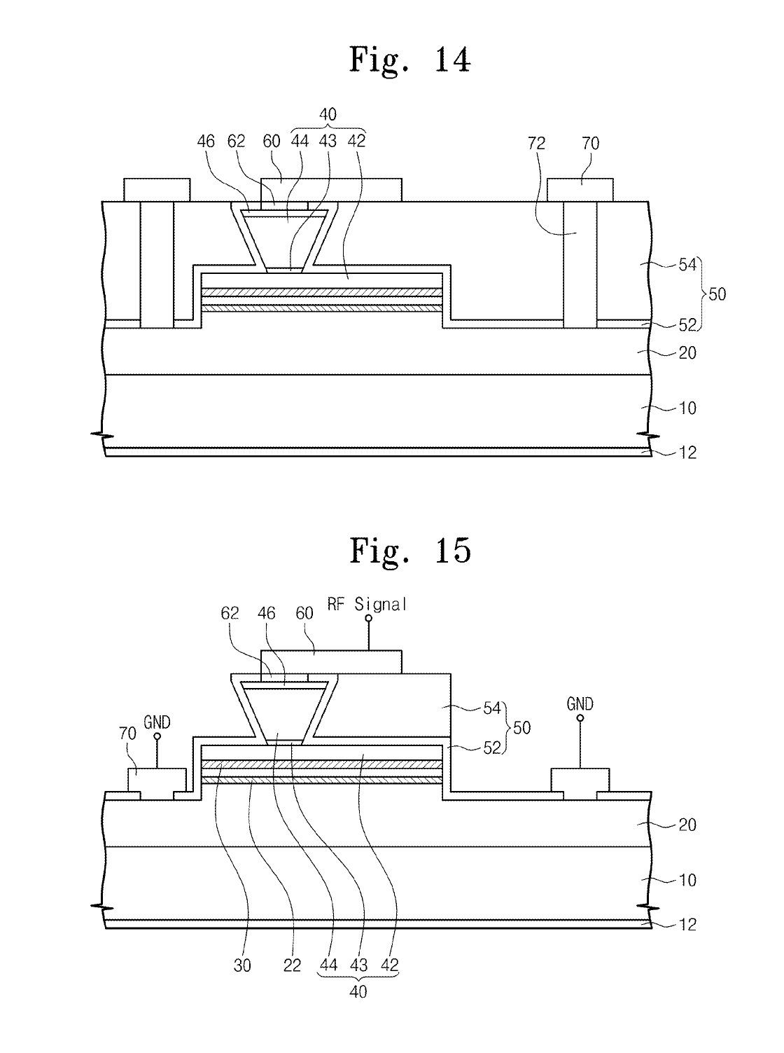

Referring to FIG. 14, the ground plate 12 is formed under the substrate. The ground plate 12 may be formed by using a thermal evaporation process, a sputtering process, or a chemical deposition process.

FIG. 15 shows a DBF-LD according to a second embodiment of the inventive concept. For the DBF-LD according to the second embodiment of the inventive concept, the lower clad layer 20 is directly connected to the ground pad 70. The second contact plugs 72 provided in the first embodiment do no exist in the second embodiment. The first passivation layer 52 of the passivation layer 50 is formed on the lower clad layer 20 and the upper clad layer 40 and on sidewalls thereof. The second passivation layer 54 is selectively disposed on the upper clad layer 40. The signal pad 60 is disposed on the first contact plug 62 and the second passivation layer 54. The ground pads 70 are disposed on a lower part than the signal pad 60. The active waveguide 30 and the upper clad layer 40 may have the higher locations than the ground pads 70.

As described above, according to the present invention, the ground pads and the signal pad are disposed on the lower clad layer and the upper clad layer. The ground pads are connected to the lower clad layer. The signal pad is connected to the upper clad layer.

The active waveguide that is extended in a first direction is disposed between the upper clad layer and the lower clad layer. The upper clad layer may be a ridge waveguide having a reverse mesa structure of an inverted triangle on the lower clad layer. The passivation layer covers the upper clad layer and the lower clad layer. The ground pads are connected to the contact plug that passes through the passivation layer. The contact plug connects the lower clad layer to the ground pads. The ground pads and the signal pad are spaced apart in a second direction. The ground pads and the signal pad are arranged in a GSG structure.

The high frequency probe module may directly detect modulation characteristics during the operation of a laser diode.

The high frequency probe module may have a plug and a plurality of probes that is fixed to the plug.

The probes may have the same length. The probes may be connected simultaneously to the signal pad and the ground pads. Thus, the DBF-LD according to the embodiments of the inventive concept may easily perform external direct modulation characteristic measurement during the operation.

While embodiments of the inventive concept are described with reference to the accompanying drawings, an ordinary person skill in the art will be able to understand that the present invention may be practiced as other particular forms without changing essential characteristics. Therefore, embodiments described above should be understood as illustrative and not limitative in every aspect.

What is claimed is:

1. A distributed feedback-laser diode (DFB-LD) comprising:
a substrate;
a lower clad layer having a grating on the substrate;
an active waveguide extended in a first direction on the lower clad layer;
an upper clad layer on the active waveguide;
a signal pad on the upper clad layer; and
at least one ground pad spaced apart from the active waveguide, the upper clad layer, and the signal pad in a second direction crossing the first direction, the at least one ground pad being coupled to the lower clad layer.

2. The distributed feedback-laser diode of claim 1, wherein the upper clad layer comprises:
a first upper clad layer covering an entire surface of the active waveguide; and
a second upper clad layer forming a ridge waveguide of the first upper clad layer.

3. The distributed feedback-laser diode of claim 2, wherein the second upper clad layer has a reverse mesa structure of an inverted triangle in the second direction.

4. The distributed feedback-laser diode of claim 3, wherein the upper clad layer further comprises an etch stop layer between the first upper clad layer and the second upper clad layer.

5. The distributed feedback-laser diode of claim 4, wherein the etch stop layer defines a depth or thickness of the reverse mesa structure.

6. The distributed feedback-laser diode of claim 2, further comprising:
a passivation layer covering the lower clad layer and the first upper clad layer; and
a first contact plug passing through the passivation layer, the first contact plug disposed between the ground pad and the lower clad layer.

7. The distributed feedback-laser diode of claim 6, wherein the passivation layer comprises:
a first passivation layer disposed on the lower clad layer and the upper clad layer and on sidewalls of the lower clad layer and the upper clad layer; and
a second passivation layer covering the first passivation layer, the second passivation layer formed in the same height as the upper clad layer.

8. The distributed feedback-laser diode of claim 2, further comprising an omic contact layer and a second contact plug between the second upper clad layer and the signal pad.

9. The distributed feedback-laser diode of claim 1, wherein the ground pad and the signal pad are arranged in a ground-signal-ground GSG structure in the second direction.

10. The distributed feedback-laser diode of claim 1, wherein the active waveguide has a multiple quantum well structure.

11. A method of manufacturing a distributed feedback-laser diode, the method comprising:
forming a lower clad layer on a substrate;
forming an active waveguide and an upper clad layer in a first direction on the lower clad layer;
forming a protective layer disposed on the upper clad layer and the lower clad layer, the protective layer having contact holes through which portions of the upper clad layer and the lower clad layer are exposed; and
forming a signal pad and a ground pad electrically coupled to the upper clad layer and the lower clad layer respectively through the contact holes.

12. The method of claim 11,
the forming of the active waveguide and the upper clad layer comprises:
forming the active waveguide on the lower clad layer;
forming a first upper clad layer on the active waveguide;
forming an etch stop layer on the first upper clad layer;
forming a second upper clad layer on the etch stop layer;
forming an omic contact layer on the second upper clad layer; and
etching the omic contact layer, the second upper clad layer, and the etch stop layer to have a reverse mesa structure of an inverted triangle.

13. The method of claim 12, wherein the etching of the omic contact layer, the second upper clad layer, and the etch stop layer is performed by using wet solution including hydrogen bromide or hydrogen chloride.
